(19) United States
(12) Patent Application Publication
(10) Pub. No.: US 2025/0227926 A1
(43) Pub. Date: Jul. 10, 2025

(54) MEMORY DEVICE INCLUDING MERGED SUB ARRAY

(71) Applicant: SAMSUNG ELECTRONICS CO., LTD., Suwon-si (KR)

(72) Inventors: Changyoung LEE, Suwon-si (KR); Sanghoon JUNG, Suwon-si (KR); Youngseok PARK, Suwon-si (KR); Changsik YOO, Suwon-si (KR); Hyunchul YOON, Suwon-si (KR); Jeogdon IHM, Suwon-si (KR)

(73) Assignee: SAMSUNG ELECTRONICS CO., LTD., Suwon-si (KR)

(21) Appl. No.: 19/008,328

(22) Filed: Jan. 2, 2025

(30) Foreign Application Priority Data
Jan. 8, 2024 (KR) 10-2024-0003125

(51) Int. Cl. H10B 12/00; H01L 23/00; H01L 25/065; H01L 25/18; H10B 80/00

(52) U.S. Cl. CPC H10B 12/50; H01L 24/08; H01L 25/0657; H01L 25/18; H10B 12/315; H10B 80/00; H01L 2224/08145; H01L 2924/1431; H01L 2924/1436

(57) ABSTRACT

A memory device includes a peripheral circuit structure and a cell array structure, in which the cell array structure overlaps the peripheral circuit structure in a first direction, in which the cell array structure includes a merged sub array in which at least four sub array regions are merged, in which the merged sub array comprises a memory cell region including: a plurality of first bit lines and a plurality of second bit lines; and a plurality of first word lines and a plurality of second word lines, in which the peripheral circuit structure comprises a merged bank in which at least four banks are merged, and in the merged bank comprises: a first bit line sense amplifier (BLSA), a second BLSA, a first sub word line driver (SWD), a second SWD, and in which a spare space is defined between the first bit lines and the second bit lines.

### CROSS-REFERENCE TO RELATED APPLICATION

This application is based on and claims priority under 35 U.S.C. § 119 to Korean Patent Application No. 10-2024-0003125, filed on Jan. 8, 2024, in the Korean Intellectual Property Office, the disclosure of which is incorporated by reference herein in its entirety.

### BACKGROUND

### 1. Field

The embodiments of the present disclosure to a semiconductor device, and

more particularly, to a memory device including a merged sub array having a word line and bit line division structure to reduce the chip size of the memory device.

### 2. Description of related art

Recently, along with the multi-functionalization of information communication devices, large-capacity and high-integration memory devices are increasing in demand. Along with a decrease in the size of a memory cell for high integration, operation circuits and/or a wiring structure included in a memory device for an operation and an electrical connection of the memory device also have become complicated. Accordingly, there is an increase in demand for a memory device having good electrical characteristics while also improving the integration of the memory device. To improve the storage capacity and integration of a memory device, a vertical channel transistor, vertically formed on a semiconductor substrate, has been introduced.

A memory device (e.g., dynamic random access memory (DRAM)), may include a plurality of memory cells each including a vertical channel transistor and a capacitor, and operate in a manner of writing and reading data by charges stored in the capacitor.

### SUMMARY

The embodiments of the present disclosure provide a memory device including a merged sub array having a word line and bit line division structure to reduce the chip size of the memory device by expanding a spare region of a merged bank.

According to an aspect of the disclosure, a memory device comprises: a peripheral circuit structure; and a cell array structure on the peripheral circuit structure, wherein the cell array structure overlaps the peripheral circuit structure in a first direction, wherein the cell array structure comprises a merged sub array in which at least four sub array regions are merged, wherein the merged sub array comprises a memory cell region comprising: a plurality of first bit lines and a plurality of second bit lines arranged in a second direction perpendicular to the first direction; and a plurality of first word lines and a plurality of second word lines arranged in a third direction that is perpendicular to the second direction, wherein the peripheral circuit structure comprises a merged bank in which at least four banks are merged, and wherein the merged bank comprises: a first bit line sense amplifier (BLSA) configured to sense a voltage difference of the plurality of first bit lines, a second BLSA configured to sense a voltage difference of the plurality of second bit lines, a first sub word line driver (SWD) configured to drive even numbered word lines among the plurality of first word lines and even numbered word lines among the plurality of second word lines, and a second SWD configured to drive odd numbered word lines among the plurality of first word lines and odd numbered word lines among the plurality of second word lines, and wherein a spare space is defined between a first area corresponding to the plurality of first bit lines and a second area corresponding to the plurality of second bit lines.

According to an aspect of the disclosure, a memory device comprising: a peripheral circuit structure; and a cell array structure on the peripheral circuit structure wherein the cell array structure overlaps the peripheral circuit structure in a first direction, wherein the cell array structure comprises a merged sub array in which at least 4n sub array regions are merged, wherein n is a natural greater than zero, wherein the merged sub array comprises: a first bit line half group and a second bit line half group obtained by dividing a plurality of first bit lines and a plurality of second bit lines arranged in a second direction perpendicular to the first direction, and a first word line half group and a second word line half group obtained by dividing a plurality of first word lines and a plurality of second word lines arranged in a third direction that is perpendicular to the second direction, and wherein the peripheral circuit structure comprises a merged bank in which at least 4n banks are merged.

According to an aspect of the disclosure, a memory device comprises: a peripheral circuit structure; and a cell array structure on the peripheral circuit structure, wherein the cell array structure overlaps the peripheral circuit structure in a first direction, wherein the cell array structure comprises a merged sub array in which at least 4n sub array regions are merged, wherein n is a natural number greater than zero, wherein the merged sub array comprises a memory cell region comprising (i) a plurality of first bit lines and a plurality of second bit lines arranged in a second direction perpendicular to the first direction and (ii) a plurality of first word lines and a plurality of second word lines arranged in a third direction perpendicular to the second direction, wherein the memory cell region comprises a first bit line half group and a second bit line half group obtained by dividing the plurality of first bit lines and the plurality of second bit lines according to first predetermined criteria and a first word line half group and a second word line half group obtained by dividing the plurality of first word lines and the plurality of second word lines according to second predetermined criteria, wherein the peripheral circuit structure comprises a merged bank in which at least 4n banks are merged, and wherein the merged bank comprises: a first bit line sense amplifier (BLSA) configured to sense a voltage difference of the plurality of first bit lines, a second BLSA configured to sense a voltage difference of the plurality of second bit lines, a first sub word line driver (SWD) configured to drive even numbered word lines among the plurality of first word lines and even numbered word lines among the plurality of second word lines, a second SWD configured to drive odd numbered word lines among the plurality of first word lines and odd numbered word lines among the plurality of second word lines, and wherein a spare space is defined between a first area corresponding to the plurality of first bit lines and a second area corresponding to the plurality of second bit lines.

### BRIEF DESCRIPTION OF DRAWINGS

The embodiments of the present disclosure will be more clearly understood from the following detailed description taken in conjunction with the accompanying drawings in which:

FIG. 1 is a block diagram of a memory device according to one or more embodiments;

FIG. 2 is a perspective view schematically illustrating a structure of a memory device according to one or more embodiments;

FIG. 3 is a circuit diagram of a memory cell array according to one or more embodiments;

FIG. 4 is a circuit diagram of parasitic capacitors included in a memory cell array according to one or more embodiments;

FIG. 5 is a perspective view particularly illustrating a structure of a memory device according to one or more comparative embodiments;

FIG. 6 is a cross-sectional view of a memory device cut along line A1-A2 of FIG. 5;

FIGS. 7A and 7B are perspective views schematically illustrating structures of memory devices according to one or more embodiments;

FIG. 8 is a perspective view illustrating a word line division structure and method according to one or more embodiments;

FIG. 9 is a perspective view illustrating a bit line division structure and method according to one or more embodiments;

FIG. 10 is a perspective view illustrating a word line and bit line division structure and method according to one or more embodiments; and

FIG. 11 is a block diagram illustrating an electronic device including a memory device according to one or more embodiments.

### DETAILED DESCRIPTION OF EMBODIMENTS

The DRAM may have a cell over periphery (CoP) structure including a cell array structure and a peripheral circuit structure vertically overlapping each other. The cell array structure may include a memory cell array including a plurality of memory cells each including a vertical channel transistor and a capacitor, and the peripheral circuit structure may include a spare region and peripheral circuits including a sub word line driver, a bit line sense amplifier, and the like. As memory sizes shrink, the ratio of the area occupied by a peripheral circuit region to the area of a memory cell array region may increase. Accordingly, the chip size of DRAM having a CoP structure may impact the area of the peripheral circuit region, which may lead to inefficient use of the spare region.

In some aspects, the area of the peripheral circuit region may be reduced or the spare region may be utilized to reduce the chip size of the DRAM.

Hereinafter, embodiments of the present disclosure are described in detail with reference to the accompanying drawings.

Terms, such as ‘upper,’ ‘upper portion,’ ‘upper surface,’ ‘lower,’ ‘lower portion,’ ‘lower surface,’ ‘side surface,’ and the like, may be understood as referring to the drawings, unless otherwise indicated by reference numerals.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

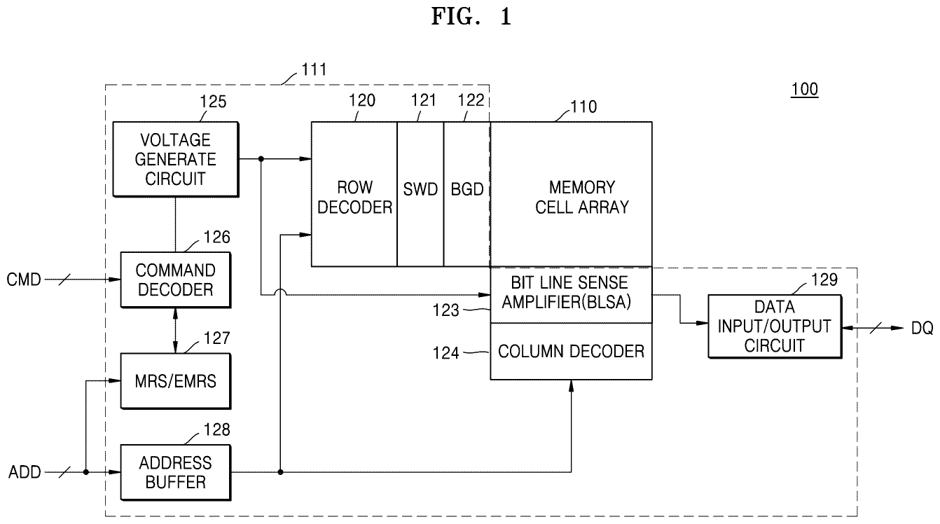

FIG. 1 is a block diagram of a memory device 100 according to one or more embodiments.

Referring to FIG. 1, the memory device 100 may correspond to, for example, double data rate synchronous dynamic random access memory (DDR SDRAM), low power double data rate (LPDDR) SDRAM, graphics double data rate (GDDR) SDRAM, Rambus dynamic random access memory (RDRAM), or any other suitable memory structure known to one of ordinary skill in the art.

The memory device 100 may include a memory cell array 110 and a peripheral circuit 111. In one or more examples, a peripheral circuit may refer to circuitry or components that are peripheral to a memory cell array.

In one or more examples, the memory cell array 110 may include a plurality of memory cells arrange in rows and columns.

In one or more examples, the peripheral circuit 111 may include a row decoder 120, a sub word line diver (SWD) 121, a back gate driver (BGD) 122, a bit line sense amplifier (BLSA) 123, a column decoder 124, a voltage generation circuit 125, a command decoder 126, a mode register set/extended mode register set (MRS/EMRS) circuit 127, an address buffer 128, and a data input/output (I/O) circuit 129.

The row decoder 120 may decode a row address in an address signal ADD output from the address buffer 128, to designate a word line connected to a memory cell to or from which data DQ is to be input or output. For example, the row decoder 120 may select a corresponding word line (e.g., referred to as a selected word line) by decoding a row address output from the address buffer 128 in a data write mode or a data read mode. In one or more examples, the row decoder 120 may generate a word line driving voltage to be applied to a word line corresponding to a row address.

The SWD 121 may apply a word line driving voltage to a word line selected based on the decoded row address. The SWD 121 may be connected to a plurality of word lines formed in each sub array region. The SWD 121 may drive one or more of the plurality of word lines by supplying the word line driving voltage to the one or more word lines. In one or more examples, the SWD 121 is configured to drive a subset of a plurality of word lines.

The BGD 122 may apply a back gate voltage to a back gate line. The BGD 122 may be implemented by a regulator (e.g., a low dropout (LDO) regulator.

In one or more examples, a BLSA a circuit that is used to amplify and detect small signals in a memory device. The BLSA 123 may sense the data DQ of a memory cell through a bit line. The BLSA 123 may sense and amplify the data DQ of the memory cell and store the data DQ in the memory cell. The BLSA 123 may be implemented by a cross-coupled amplifier connected between a bit line and a complementary bit line (e.g., a bit line bar) included in the memory cell array 110.

In one or more examples, the column decoder 124 may decode a column address in the address signal ADD output from the address buffer 128, to designate a bit line connected to the memory cell to or from which the data is to be input or output. The memory cell array 110 may output the data from the memory cell designated by the row and column addresses or write the data to the memory cell.

In one or more examples. the voltage generate circuit 125 may generate various internal voltages for driving circuits in the memory device 100. The voltage generate circuit 125 may generate a high voltage (e.g., VPP), a negative voltage (e.g., VBB), a bit line precharge voltage (e.g., VEQ), an internal power source voltage (e.g., VINTA), or any other suitable voltage by using a power source voltage (e.g., VDD) applied from the outside of the memory device 100. The high voltage (e.g., VPP) may be provided to the row decoder 120, have a higher voltage level than the power source voltage (e.g., VDD), and be used for word line driving circuits to turn on N-type metal oxide semiconductor (NMOS) cell transistors connected to word lines. The negative voltage (e.g., VBB) may have a negative (−) voltage level lower than the power source voltage (e.g., VDD) and be used to increase a data retention time by increasing the threshold voltage (e.g., Vth) of an NMOS transistor. The negative voltage (e.g., VBB) may be applied to a well region in which an NMOS transistor is formed and usually referred to as a bulk bias voltage or a back bias voltage. The bit line precharge voltage (e.g., VEQ) may be used to equalize a bit line (e.g., BL) and a bit line bar (e.g., BLB) before the BLSA 123 senses the voltage difference between the bit line (e.g., BL) and the bit line bar (e.g., BLB). The internal power source voltage (e.g., VINTA) may be provided to first and second sensing driving voltage lines (e.g., LA and LAB) of the BLSA 123. The BLSA 123 may sense and amplify the voltage difference between the bit line (e.g., BL) and the bit line bar (e.g., BLB) according to the first and second sensing driving voltage lines (e.g., LA and LAB).

In one or more examples, the command decoder 126 may receive a command signal CMD applied from the outside of the memory device 100 and decode the command signal CMD to internally generate a command according to the decoded command signal.

In one or more examples, the MRS/EMRS circuit 127 may configure an internal mode register in response to an MRS/EMRS command for designating an operation mode of the memory device 100 and the address signal ADD. The MRS/EMRS circuit 127 may be programmed to set operation parameters, options, various functions, characteristics, and modes of the memory device 100. The MRS/EMRS circuit 127 may store a parameter code including proper bit values provided through a command/address (CA) bus of a memory bus when an MRS command is issued from a memory controller coupled to the memory device 100.

The data DQ input through the data I/O circuit 129 may be written to the memory cell array 110 based on the address signal ADD, and the data DQ read from the memory cell array 110 based on the address signal ADD may be output to the outside through the data I/O circuit 129. To designate a memory cell to or from which data is to be written or read, the address signal ADD may be input to the address buffer 128. For example, the data DQ, which is input to the memory device 100, may be written to each sub array, or the data DQ read from each sub array may be output to the outside through the data I/O circuit 129.

The address buffer 128 may temporarily store the address signal ADD input from the outside. When a memory cell is read corresponding to the address signal ADD, the stored address signal ADD may be removed from the address buffer 128.

The memory device 100 may further include a clock circuit configured to generate a clock signal, a power source generation circuit configured to receive a power source voltage applied from the outside and generate or distribute internal voltages, a voltage detection circuit configured to detect a voltage level, a test circuit capable of performing a test operation in the memory device 100, a control circuit configured to control an operation of the circuits in the peripheral circuit 111, or any other suitable circuit structure known to one of ordinary skill in the art.

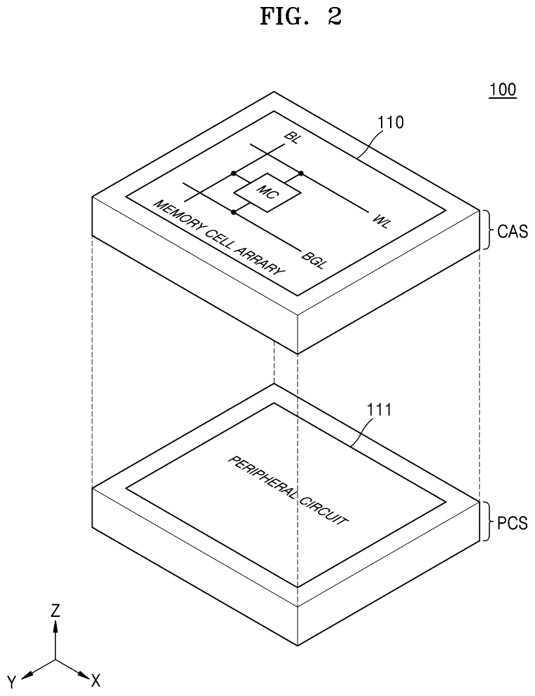

FIG. 2 is a perspective view schematically illustrating a structure of the memory device 100 according to one or more embodiments.

Referring to FIG. 2, the memory device 100 may include a cell array structure CAS and a peripheral circuit structure PCS. The cell array structure CAS may be on the peripheral circuit structure PCS in the vertical direction (e.g., the Z direction, first direction). For example, the peripheral circuit structure PCS may be under the cell array structure CAS in the vertical direction. In some embodiments, the cell array structure CAS and the peripheral circuit structure PCS may adhere to each other through pads in the vertical direction (e.g., the Z direction, first direction). An adhering scheme may be, for example, bonding between a copper (Cu) pad and a Cu pad, but is not limited thereto. In one or more examples, a first set of pads may be adhered to the CAS, and a second set of pads may be adhered to the PCS, where a pad from the first set of pads is adhered to a respective pad in the second set of pads. Other bonding techniques may include silicon direct bonding, anodic bonding, etc.

The cell array structure CAS may include the memory cell array 110 of FIG. 1. According to one or more embodiments, the memory cell array 110 may include a plurality of word lines, a plurality of bit lines, and a plurality of back gate lines connected to a plurality of memory cells. For example, bit lines BL may extend in a first horizontal direction (e.g., the Y direction) and be arranged in parallel in a second horizontal direction (e.g., the X direction). Word lines WL may extend in the second direction (e.g., the X direction) and be arranged in parallel in the first direction (e.g., the Y direction), and back gate lines BGL may extend in the second direction (e.g., the X direction) and be arranged in parallel in the first direction (e.g., the Y direction). A memory cell MC may be connected each of a bit line BL, a word line WL, and a back gate line BGL. The memory cell MC may include a cell transistor and a cell capacitor. In some embodiments, the cell transistor may include a forward gate connected to the word line WL and a back gate connected to the back gate line BGL. The memory cell MC may share the back gate with an adjacent memory cell through one back gate line BGL.

The peripheral circuit structure PCS may include the peripheral circuit 111 of FIG. 1. According to one or more embodiments, the peripheral circuit 111 may be configured to apply the word line driving voltage to a word line (e.g., WL) selected from among the plurality of word lines. The peripheral circuit 111 may be configured to apply a back gate voltage to a back gate line (e.g., BGL) connected to memory cells (e.g., MC) connected to the selected word line (e.g., WL). The peripheral circuit 111 may be configured to sense data through at least one bit line (e.g., BL) selected from among the plurality of bit lines.

Because the memory device 100 according to the embodiments of the present disclosure includes a stacked structure of the cell array structure CAS and the peripheral circuit structure PCS, word lines may extend without being cut by a circuit component other than memory cells in the cell array structure CAS. For example, the stacked structure provides additional space for the word lines compared to a non-stacked structure where a PCS and a CAS are included on a same plane.

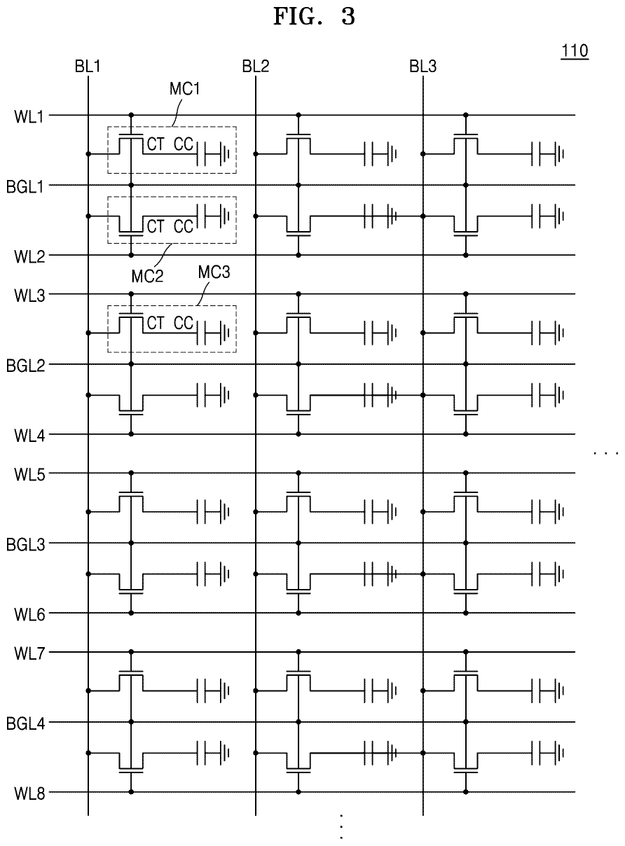

FIG. 3 is a circuit diagram of the memory cell array 110 according to one or more embodiments.

Referring to FIGS. 2 and 3, the memory cell array 110 may include the plurality of word lines (e.g., WL), the plurality of bit lines (e.g., BL), the plurality of back gate lines (e.g., BGL), and the plurality of memory cells (e.g., MC).

FIG. 3 illustrates first to eighth word lines WL1, WL2, WL3, WL3, WL4, WL5, WL6, WL7, and WL8, first to third bit lines BL1, BL2, and BL3, first to fourth back gate lines BGL1, BGL2, BGL3, BGL3, and BGL4, and 24 memory cells. However, the memory cell array 110 according to the embodiments of the present disclosure are not limited thereto. In this regard, as understood by one of ordinary skill in the art, the memory cell array may include fewer or more word lines, bit lines, back gate lines, and memory cells.

Each of the plurality of memory cells may include a cell transistor CT and a cell capacitor CC. The cell transistor CT may include a forward gate connected to a word line, a back gate shared with an adjacent cell transistor CT through a back gate line, and a plurality of electrodes. The cell transistor CT may store a charge corresponding to memory information. For example, the cell transistor CT that stores a charge may correspond to a binary “1”, whereas the cell transistor CT that does not store the charge may correspond to a binary “0”.

For example, a cell transistor CT of a first memory cell MC1 may include a forward gate connected to the first word line WL1, a back gate connected to the first back gate line BGL1, a first electrode connected to a cell capacitor CC, and a second electrode connected to the first bit line BL1. For example, a cell transistor CT of a second memory cell MC2 may include a forward gate connected to the second word line WL2, a back gate connected to the first back gate line BGL1, a first electrode connected to a cell capacitor CC, and a second electrode connected to the first bit line BL1. For example, a cell transistor CT of a third memory cell MC3 may include a forward gate connected to the third word line WL3, a back gate connected to the second back gate line BGL2, a first electrode connected to a cell capacitor CC, and a second electrode connected to the first bit line BL1.

In one or more examples, the cell transistor CT of the first memory cell MC1 and the cell transistor CT of the second memory cell MC2 may share the back gates of the first and second memory cells MC1 and MC2 through the first back gate line BGL1. The cell transistor CT of the first memory cell MC1 and the cell transistor CT of the second memory cell MC2 may be adjacent cell transistors.

In some embodiments, a channel of the cell transistor CT may be formed in the vertical direction (e.g., the Z direction, first direction). The cell transistor CT including the channel formed in the vertical direction (e.g., the Z direction, first direction) may be referred to as a vertical channel transistor. In some embodiments, the cell transistor CT may be implemented by an n-type transistor, but is not limited thereto. When the back gate is included in the cell transistor CT, a floating body may be controlled and the threshold voltage of the cell transistor CT may be easily controlled.

In one or more examples, when the cell transistor CT shares the back gate with an adjacent cell transistor, the chip size of the memory device 100 may decrease and the memory device 100 may be further integrated. In some embodiments, a back gate may be shared for every two word lines. However, the embodiments of the present disclosure are not limited thereto.

The cell capacitor CC may store charges of a capacity corresponding to single-bit data (e.g., bit ‘0’ or bit ‘1’). According to one or more embodiments, the cell capacitor CC may store charges of a capacity corresponding to multi-bit data (e.g., two-bit data). The cell capacitor CC may be restored to charges corresponding to the capacity of single-bit data or multi-bit data. The cell capacitor CC may be connected between the first electrode of the cell capacitor CC and ground. For example, a first electrode of the cell capacitor CC may be connected to the first electrode of the cell transistor CT and a second electrode of the cell capacitor CC may be connected to ground.

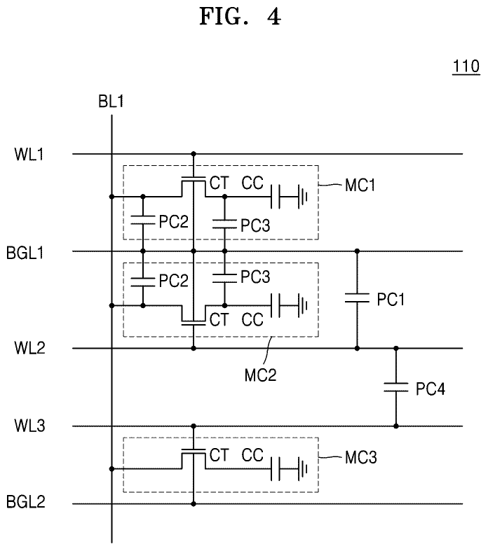

FIG. 4 is a circuit diagram of parasitic capacitors included in the memory cell array 110 according to one or more embodiments. Parasitic capacitance may refer to capacitance that exits between parts of electronic components or circuits due to their proximity to each other. For example, when two electrical conductors at different voltages are close together, the electric field between them causes electric charge to be stored on them, thereby causing parasitic capacitance For convenience of description, first to fourth parasitic capacitors PC1, PC2, PC3, and PC4 shown in FIG. 4 are described below with reference to the first bit line BL1, the first to third word lines WL1, WL2, and WL3, the first and second back gate lines BGL1 and BGL2, and the first to third memory cells MC1, MC2, and MC3.

Referring to FIG. 4, the first and second memory cells MC1 and MC2 may be connected to the first back gate line BGL1 and the third memory cell MC3 may be connected to the second back gate line BGL2. Because the first parasitic capacitor PC1, due to coupling between the first back gate line BGL1 and the second word line WL2, is present, the potential of the first back gate line BGL1 may change or ripple in response to applying the word line driving voltage to the second word line WL2. If the potential of the first back gate line BGL1 ripples, due to the second and third parasitic capacitors PC2 and PC3 between the first back gate line BGL1 and the cell transistor CT of the first memory cell MC1, the potentials of the first electrode and the second electrode of the cell transistor CT of the first memory cell MC1 may also ripple and the potential of the first word line WL1 may also ripple. As a result, because the potential of the first word line WL1 also ripples, the threshold voltage of the cell transistor CT of the first memory cell MC1 may change (e.g., decrease).

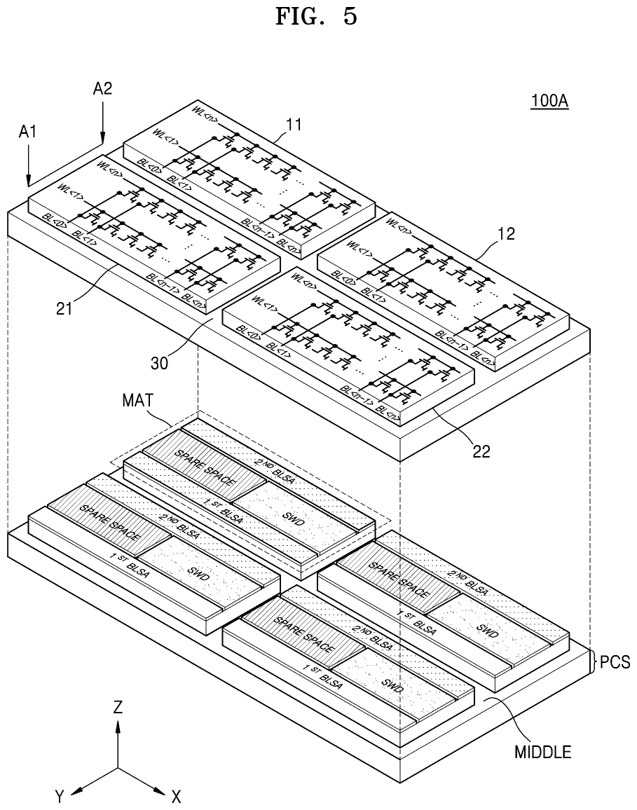

FIG. 5 is a perspective view schematically illustrating a structure of a memory device 100A according to one or more comparative embodiments. The memory device 100A of FIG. 5 may be a modified embodiment of the memory device 100 shown in FIG. 2. The description made with reference to FIG. 2 is omitted herein.

The cell array structure CAS may include a plurality of sub array regions 11, 12, 21, and 22 and a dummy region.

Each of the plurality of sub array regions 11, 12, 21, and 22 may include a plurality of word lines WL<1> to WL<n>, a plurality of bit lines BL<1>, BL<2>, . . . , BL<n−1>, and BL<n>, and a plurality of memory cells. The plurality of bit lines BL<1>, BL<2>, . . . , BL<n−1>, and BL<n> included in each sub array region may extend in the first horizontal direction (e.g., the Y direction, second direction) and be arranged in parallel in the second horizontal direction (e.g., the X direction, third direction). The plurality of word lines WL<1> to WL<n>included in each sub array region may extend in the second horizontal direction (e.g., the X direction) and be arranged in parallel in the first horizontal direction (e.g., the Y direction). Each memory cell may be connected to each of the plurality of bit lines BL<1>, BL<2>, . . . , BL<n−1>, and BL<n> and each of the plurality of word lines WL<1> to WL<n>.

Each memory cell may include a cell transistor and a cell capacitor. Each of the memory cells formed in the plurality of sub array regions 11, 12, 21, and 22 may include a cell transistor connected to a bit line BL and a word line WL and a cell capacitor. The plurality of sub array regions 11, 12, 21, and 22 may be included in one memory block. For example, memory cells connected to the plurality of word lines WL<1> to WL<n>may constitute one memory block. The plurality of sub array regions 11, 12, 21, and 22 may be arranged such that at least one side of each of the plurality of sub array regions 11, 12, 21, and 22 is spaced apart from another sub array region. Each of the plurality of sub array regions 11, 12, 21, and 22 may include a plurality of pads formed so that the peripheral circuit structure PCS to be connected to each of the plurality of bit lines BL<1>, BL<2>, . . . , BL<n−1>, and BL<n> and the plurality of word lines WL<1> to WL<n>. For example, each sub array region may include first pads and second pads. The first pads may connect a BLSA of the peripheral circuit structure PCS to the plurality of bit lines BL<1>, BL<2>, . . . , BL<n−1>, and BL<n>. The second pads may connect an SWD of the peripheral circuit structure PCS to the plurality of word lines WL<1> to WL<n>. For example, each of regions 11, 12, 21, and 22 may be associated with corresponding first and second BLSAs, a SWD, and a share space in the PCS.

The dummy region may be between the plurality of sub array regions 11, 12, 21, and 22. For example, a dummy region 30 may be between two different sub array regions. The dummy region 30 may be in parallel to each sub array region in a horizontal direction. The dummy region 30 may include a plurality of pads connected to the peripheral circuit structure PCS. In some embodiments, the dummy region 30 may not include the plurality of bit lines BL<1>, BL<2>, . . . , BL<n−1>, and BL<n>, the plurality of word lines WL<1> to WL<n>, and a plurality of memory cells. In one or more examples, a dummy region may be referred to an inactive region where circuits are not included.

The peripheral circuit structure PCS may include a peripheral circuit region in which a peripheral circuit is formed. One or more peripheral circuits may be formed in a partial region of the peripheral circuit region. One or more other peripheral circuits may be formed in another partial region of the peripheral circuit region. The peripheral circuit may be configured to apply the word line driving voltage to a word line selected from among the plurality of word lines WL<1> to WL<n>. The peripheral circuit may be configured to sense data through at least one bit line selected from among the plurality of bit lines BL<1>, BL<2>, . . . , BL<n−1>, and BL<n>.

In one or more examples, the peripheral circuit may include a row decoder, a column decoder, or any other suitable component known to one of ordinary skill in the art. In one or more examples, a middle region MIDDLE or a spare region SPARE of the peripheral circuit structure PCS may include the command decoder 126, the MRS/EMRS circuit 127, the address buffer 128, the data I/O circuit 129, the voltage generate circuit 125, a test circuit, shown in FIG. 1, or any other circuit structure known to one of ordinary skill in the art. Although FIG. 5 illustrates regions 11, 12, 21, and 22 being an equal size, the embodiments of the present disclosure are not limited to these configurations. For example, at least one of the regions 11, 12, 21, and 22 may be a different size than the other regions.

For example, each of regions other than the middle region MIDDLE or a spare region of the peripheral circuit structure PCS may include a row decoder, a column decoder, and a bank. The bank may include one or more mats. One mat may include a first BLSA BLSA1, a second BLSA, and an SWD. One mat may further include a conjunction.

Because the memory device 100A according to the embodiments of the present disclosure include a stacked structure of the cell array structure CAS and the peripheral circuit structure PCS, word lines may extend without being cut by a circuit component other than memory cells in the cell array structure CAS. For example, because the PCS is on a different plane than the CAS, there is an additional space for the wordlines.

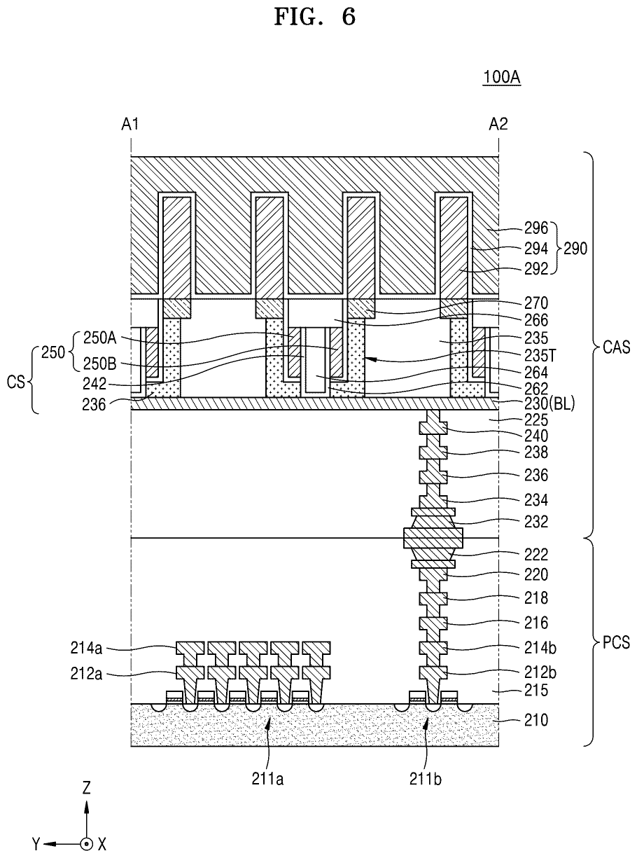

FIG. 6 is a cross-sectional view of the memory device 100A cut along line A1-A2 of FIG. 5.

Referring to FIG. 6, the memory device 100A may include the cell array structure CAS and the peripheral circuit structure PCS adhering to each other in the vertical direction (e.g., the Z direction). Because the cell array structure CAS may include the plurality of sub array regions 11, 12, 21, and 22 and the peripheral circuit structure PCS may include a peripheral circuit, the memory device 100A may have a structure in which a sub array is over a peripheral circuit (e.g., a CoP structure). As understood by one of ordinary skill in the art, a COP structure provides a three-dimensional memory device including a plurality of memory cells stacked repeatedly with respect to a surface, which advantageously results in a high degree of integration.

In one or more examples, the cell array structure CAS may include a memory cell including a vertical channel transistor. A bit line BL may extend in the first horizontal direction (e.g., the Y direction), and a word line WL may extend in the second horizontal direction (e.g., the X direction). Each of the memory cell, the bit line BL, and the word line WL may be plural in number.

In one or more examples, the peripheral circuit structure PCS may include a semiconductor substrate, wherein the peripheral circuit may be formed by forming, on the semiconductor substrate, semiconductor devices, such as a transistor, and a pattern for wiring devices. After forming the peripheral circuit in the peripheral circuit structure PCS, the cell array structure CAS including the plurality of sub array regions 11, 12, 21, and 22 and the dummy region 30 may be formed and patterns for electrically connecting a word line WL and a bit line BL in each sub array region to the peripheral circuit formed in the peripheral circuit structure PCS may be formed.

In one or more examples, the peripheral circuit structure PCS may include a substrate 210, a first interlayer insulating layer 215, a plurality of circuit devices (e.g., first and second circuit devices 211a and 211b), formed on the substrate 210, first metal patterns 212a and 212b, respectively, connected to the first and second circuit devices 211a and 211b, second metal patterns 214a and 214b respectively formed on the first metal patterns 212a and 212b, a third metal pattern 216 formed on the second metal pattern 214b, a fourth metal pattern 218 formed on the third metal pattern 216, a fifth metal pattern 220 formed on the fourth metal pattern 218, and a first pad 222 formed on the fifth metal pattern 220.

Although only the first metal pattern 212a and the second metal pattern 214a are shown in FIG. 6, the peripheral circuit structure PCS is not limited thereto, and at least one metal pattern may be further formed on the second metal pattern 214a. A metal pattern may also be referred to as a metal layer. In some embodiments, a metal pattern may include at least one metal line extending in one horizontal direction and arranged in parallel in the other horizontal direction. Although only the first metal pattern 212b, the second metal pattern 214b, the third metal pattern 216, the fourth metal pattern 218, and the fifth metal pattern 220 are shown in FIG. 6, the peripheral circuit structure PCS is not limited thereto, and a fewer number of metal patterns than five metal patterns may be stacked or at least one metal pattern may be further formed on the fifth metal pattern 220. In one or more embodiments, the first metal patterns 212a and 212b may be formed of tungsten having a relatively high resistance value and the second metal patterns 214a and 214b may be formed of Cu having a relatively low resistance value. At least some of one or more metal patterns formed on the second metal patterns 214a and 214b may be formed of aluminum, or any other suitable material, having a lower resistance value than Cu forming the second metal patterns 214a and 214b.

The first interlayer insulating layer 215 may be on the substrate 210. The first interlayer insulating layer 215 may cover the first and second circuit devices 211a and 211b, the first metal patterns 212a and 212b, the second metal patterns 214a and 214b, the third metal pattern 216, the fourth metal pattern 218, the fifth metal pattern 220, and the first pad 222. The first interlayer insulating layer 215 may include an insulating material, such as silicon oxide or silicon nitride.

The first and second circuit devices 211a and 211b may be connected to at least one of circuit devices constituting the peripheral circuit. For example, the first circuit device 211a may be any one of transistors included in an SWD. The second circuit device 211b may be any one of transistors included in a BLSA. However, the embodiments of the present disclosure are not limited thereto.

The first pad 222 may be on the top metal pattern of the peripheral circuit structure PCS and adhere to a second pad 232. The first pad 222 may be formed of Cu but is not limited thereto.

The cell array structure CAS may include the second pad 232, a plurality of metal patterns 234, 236, 238, and 240 stacked on the second pad 232, a second interlayer insulating layer 225, a conductive line 230 on the second interlayer insulating layer 225, a cell structure CS on the conductive line 230, and a capacitor structure 290 on the cell structure CS.

The second pad 232 may be beneath the bottom metal pattern of the cell array structure CAS and adhere to the first pad 222. The second pad 232 may be formed of Cu, but is not limited thereto.

Although FIG. 6 shows that the cell array structure CAS includes four metal patterns, the cell array structure CAS is not limited thereto, and a fewer number of metal patterns than four metal patterns may be stacked or at least one metal pattern may be further formed on the second pad 232 or beneath the conductive line 230. In one or more examples, more than four metal patters may be included. In one or more embodiments, the plurality of metal patterns 234, 236, 238, and 240 may be formed of a material (e.g., Cu, tungsten, aluminum, or any other suitable material) having a certain resistance value.

In one or more examples, the second interlayer insulating layer 225 may be formed to cover the side surfaces of the second pad 232, the side surfaces of the plurality of metal patterns 234, 236, 238, and 240, and the lower surface and the side surfaces of the conductive line 230. The second interlayer insulating layer 225 may be formed to fill a space among the second pad 232, the plurality of metal patterns 234, 236, 238, and 240, and the conductive line 230.

In one or more examples, the conductive line 230 may extend in the first horizontal direction (e.g., the Y direction). Conductive lines 230 may be spaced apart from each other in the second horizontal direction (e.g., the X direction) that is perpendicular to the first horizontal direction (e.g., the Y direction). The conductive line 230 may function as a bit line BL of the memory device 100A.

In one or more examples, an isolation insulating layer 235 may be formed on the conductive line 230. The isolation insulating layer 235 may include a channel trench 235T and a plurality of insulating patterns spaced apart from each other by the channel trench 235T. A channel layer 236 may be formed in the channel trench 235T. The channel layer 236 may extend along the side surfaces and the bottom surface of the channel trench 235T and be electrically connected to the conductive line 230. A gate dielectric layer 242 may be formed on the channel layer 236 in the channel trench 235T. The gate dielectric layer 242 may be between the channel layer 236 and a gate electrode 250. The gate electrode 250 may be formed on the gate dielectric layer 242 in the channel trench 235T. In some embodiments, the gate electrode 250 may include a first gate electrode 250A and a second gate electrode 250B opposite to each other in one channel trench 235T. In this case, a structure of two transistors per channel layer 236 may be implemented. The first gate electrode 250A may function as a first word line of a sub array and the second gate electrode 250B may function as a second word line of the sub array.

In some embodiments, a barrier insulating layer 262 and a gap-fill insulating layer 264 may be formed between the first gate electrode 250A and the second gate electrode 250B. The first gate electrode 250A and the second gate electrode 250B may be separated from each other by the barrier insulating layer 262 and the gap-fill insulating layer 264. The gap-fill insulating layer 264 may be formed on the barrier insulating layer 262 and fill a region between the first gate electrode 250A and the second gate electrode 250B.

In one or more examples, the cell structure CS may include a structure of a vertical channel transistor. The vertical channel transistor may indicate a structure in which the channel length of the channel layer 236 extends in the vertical direction (e.g., the Z direction) that is perpendicular to the upper surface of the substrate 210. The vertical channel transistor may include the channel layer 236, the gate electrode 250, and the gate dielectric layer 242 between the channel layer 236 and the first gate electrode 250A. The channel layer 236 of the vertical channel transistor may include a first source/drain region and a second source/drain region disposed in the vertical direction (e.g., the Z direction). For example, a lower portion of the channel layer 236 (e.g., horizontal portion) may function as the first source/drain region and an upper portion of the channel layer 236 (e.g., vertical portion having width narrower than the horizontal portion) may function as the second source/drain region. A portion of the channel layer 236 between the first source/drain region and the second source/drain region may function as a channel region.

In one or more examples, a contact layer 270 in contact with the upper surface of the channel layer 236 may be formed on the channel layer 236. The contact layer 270 may connect the channel layer 236 to the capacitor structure 290. The upper surface of the channel layer 236 adjacent to the first gate electrode 250A may be in contact with one contact layer 270 and the upper surface of the channel layer 236 adjacent to the second gate electrode 250B may be in contact with a different contact layer 270.

In one or more examples, the capacitor structure 290 may be formed on the isolation insulating layer 235 and the contact layer 270. The capacitor structure 290 may be in contact with the upper surface of the contact layer 270. The capacitor structure 290 may be controlled by the conductive line 230 and the gate electrode 250 to store data therein. The capacitor structure 290 may include a lower electrode 292, a capacitor dielectric layer 294, and an upper electrode 296. The capacitor structure 290 may store charges in the capacitor dielectric layer 294 by using the potential difference occurring between the lower electrode 292 and the upper electrode 296.

In one or more examples, one of a plurality of vertical channel transistor structures and one of capacitor structures 290 may constitute a memory cell, and thus, the cell array structure CAS may include a plurality of memory cells including a plurality of cell structures CS and a plurality of capacitor structures 290.

According to the demand of a high-performance and high-integration memory device, the integration and the complexity of the peripheral circuit in the peripheral circuit structure PCS may increase and the complexity of wiring for signal communication between circuits (e.g., a row decoder (R/D), a column decoder (C/D), and the like) may increase. To increase the signal rate between circuits of a high-performance peripheral circuit, the wiring for signal communication may be arranged in a non-complex manner. However, due to limitation of the physical size of the peripheral circuit structure PCS, there may be lack of a space in which wiring connecting circuits to each other in the peripheral circuit structure PCS is to occupy. To solve this situation, a merged sub array in which a plurality of sub arrays included in the cell array structure CAS are merged may be included and word lines and bit lines included in the merged sub array may be divided and arranged according to predetermined criteria to increase the size of a spare region of the peripheral circuit structure PCS. If the size of the spare region increases, the spare region may include peripheral circuits, and thus, the spare region may be efficiently used and a memory chip size may decrease.

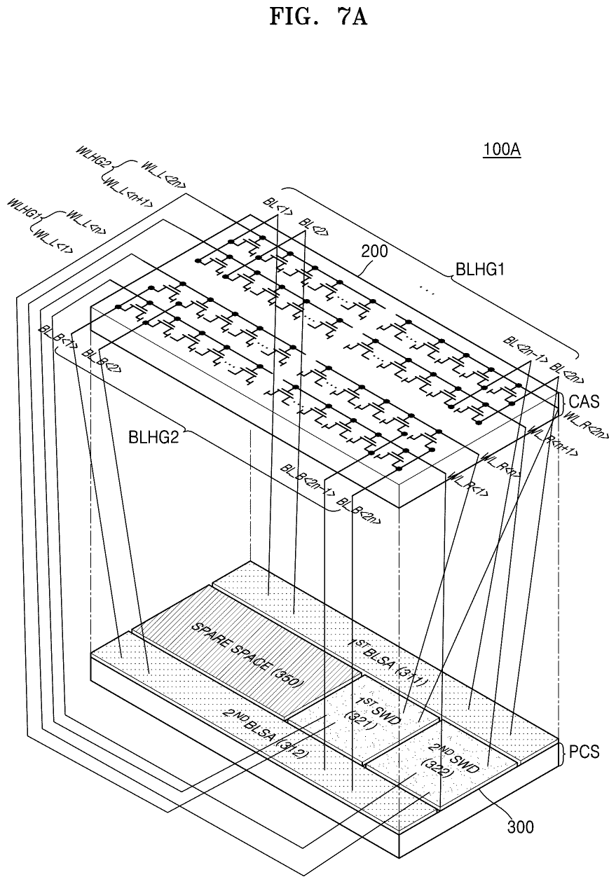

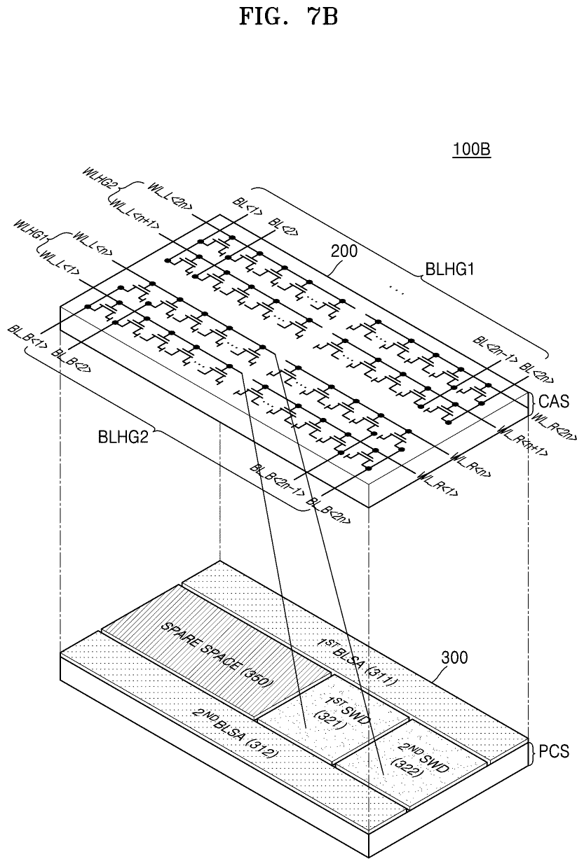

FIGS. 7A and 7B are perspective views schematically illustrating structures of memory devices 100A and 100B according to one or more embodiments.

The memory devices 100A and 100B of FIGS. 7A and 7B may be memory devices in which the plurality of, i.e., four, sub array regions 11, 12, 21, and 22 of FIG. 5 are merged. The description made with reference to FIG. 5 is omitted herein.

Referring to FIGS. 7A and 7B, the memory devices 100A and 100B may include the cell array structure CAS and the peripheral circuit structure PCS.

The cell array structure CAS may include a merged sub array 200. The merged sub array 200 may include a plurality of left word lines (e.g., first word lines) WL_L<1>, WL_L<2>, . . . , WL_L<2n−1>, and WL_L<2n>, a plurality of right word lines (e.g., second word lines) WL_R<1>, WL_R<2>, . . . , WL_R<2n−1>, and WL_R<2n>, a plurality of upper bit lines (e.g., first bit lines) BL<1>, BL<2>, . . . , BL<2n−1>, and BL<2n>, a plurality of lower bit lines (e.g., second bit lines) BL_B<1>, BL_B<2>, . . . , BL_B<2n−1>, and BL_B<2n>, and a plurality of memory cells.

Each of the numbers of left word lines WL_L<1>, WL_L<2>, . . . , WL_L<2n−1>, and WL_L<2n>, right word lines WL_R<1>, WL_R<2>, . . . , WL_R<2n−1>, and WL_R<2n>, and upper bit lines BL<1>, BL<2>, . . . , BL<2n−1>, and BL<2n> may be 2n (n is a natural number).

The plurality of upper bit lines BL<1>, BL<2>, . . . , BL<2n−1>, and BL<2n> and the plurality of lower bit lines BL_B<1>, BL_B<2>, . . . , BL_B<2n−1>, and BL_B<2n> included in the merged sub array 200 may extend in the first horizontal direction (e.g., the Y direction) and be arranged in parallel in the second horizontal direction (e.g., the X direction). The plurality of left word lines WL_L<1>, WL_L<2>, . . . , WL_L<2n−1>, and WL_L<2n> and the plurality of right word lines WL_R<1>, WL_R<2>, . . . , WL_R<2n−1>, and WL_R<2n>included in the merged sub array 200 may extend in the second horizontal direction (e.g., the X direction) and be arranged in parallel in the first horizontal direction (e.g., the Y direction).

In some embodiments, complementary bit lines of the plurality of upper bit lines BL<1>, BL<2>, . . . , BL<2n−1>, and BL<2n> may be a plurality of lower bit lines of a merged sub array adjacent to the merged sub array 200 at a side of a first BLSA 311 and complementary bit lines of the plurality of lower bit lines BL_B<1>, BL_B<2>, . . . , BL_B<2n−1>, and BL_B<2n> may be a plurality of upper bit lines of a merged sub array adjacent to the merged sub array 200 at a side of a second BLSA 312, but the some embodiments are not limited thereto.

Each memory cell may be connected to one bit line and one word line among the plurality of upper bit lines BL<1>, BL<2>, . . . , BL<2n−1>, and BL<2n>, the plurality of lower bit lines BL_B<1>, BL_B<2>, . . . , BL_B<2n−1>, and BL_B<2n>, the plurality of left word lines WL_L<1>, WL_L<2>, . . . , WL_L<2n−1>, and WL_L<2n>, and the plurality of right word lines WL_R<1>, WL_R<2>, . . . , WL_R<2n−1>, and WL_R<2n>. Each memory cell may include a cell transistor and a cell capacitor. Each memory cell formed in the merged sub array 200 may include a cell capacitor and a cell transistor connected to one bit line and one word line among the plurality of upper bit lines BL<1>, BL<2>, . . . , BL<2n−1>, and BL<2n>, the plurality of lower bit lines BL_B<1>, BL_B<2>, . . . , BL_B<2n−1>, and BL_B<2n>, the plurality of left word lines WL_L<1>, WL_L<2>, . . . , WL_L<2n−1>, and WL_L<2n>, and the plurality of right word lines WL_R<1>, WL_R<2>, . . . , WL_R<2n−1>, and WL_R<2n>.

Referring to FIGS. 7A and 7B, the peripheral circuit structure PCS may include a merged bank 300. The merged bank 300 may include one mat, wherein the one mat may include the first BLSA 311, the second BLSA 312, a spare space 350, a first SWD 321, and a second SWD 322. Accordingly, compared to FIG. 5, the entire area of the PCS is dedicated to one mat rather than a plurality of mats.

In one or more embodiments, n right word lines among the plurality of right word lines WL_R<1>, WL_R<2>, . . . , WL_R<2n−1>, and WL_R<2n> may be connected to the first SWD 321 and the other n right word lines may be connected to the second SWD 322. N left word lines among the plurality of left word lines WL_L<1>, WL_L<2>, . . . , WL_L<2n−1>, and WL_L<2n> may be connected to the first SWD 321 and the other n left word lines may be connected to the second SWD 322. N upper bit lines among the plurality of upper bit lines may be connected to the first BLSA 311 and the other n upper bit lines among the plurality of upper bit lines may be connected to the second BLSA 312. N upper bit lines among the plurality of lower bit lines may be connected to the first BLSA 311 and the other n upper bit lines among the plurality of lower bit lines may be connected to the second BLSA 312. Although FIG. 7A illustrates a disconnection between the groups of bit lines and word lines, this disconnection may be for only illustrative purposes to show that a plurality of bit lines may be divided into a upper bit lines (e.g., first bit lines) and lower bit lines (e.g., second bit lines) and that a plurality of word lines may be divided into left word lines (e.g., first word lines) and right word lines (e.g., second word lines).

For example, when n is 4, the cell array structure CAS may include eight right word lines WL_R<1> to WL_R<8>, eight left word lines WL_L<1> to WL_L<8>, eight upper bit lines BL<1> to BL<8>, and eight lower bit lines BL_B<1> to BL_B<8>.

As shown in FIGS. 7A and 7B, the odd right word lines WL_R<1>, WL_R<3>, WL_R<5>, and WL_R<7>among the eight right word lines WL_R<1> to WL_R<8> may be connected to the first SWD 321 and the other right word lines, i.e., the even right word lines WL_R<2>, WL_R<4>, WL_R<6>, and WL_R<8>, may be connected to the second SWD 322. The eight upper bit lines BL<1> to BL<8> may be connected to the first BLSA 311 and the eight lower bit lines BL_B<1> to BL_B<8> may be connected to the second BLSA 312.

However, embodiments are not limited thereto, and as another example, four right word lines (e.g., WL_R<1>, WL_R<2>, WL_R<3>, and WL_R<4>) among the eight right word lines WL_R<1> to WL_R<8> may be connected to the first SWD 321 and the other four right word lines (e.g., WL_R<5>, WL_R<6>, WL_R<7>, and WL_R<8>) may be connected to the second SWD 322.

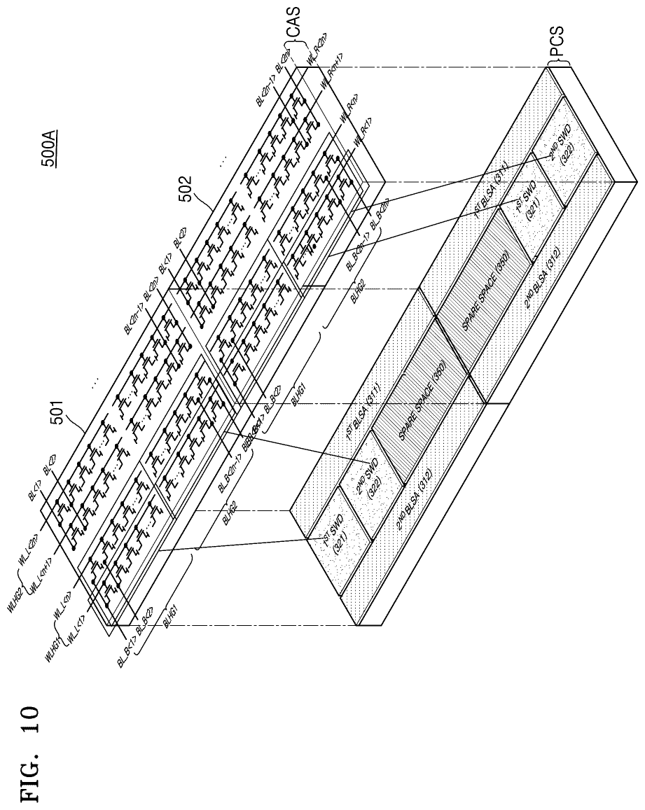

Although FIGS. 7A and 7B show one merged sub array 200, the present embodiment is not limited thereto. The cell array structure CAS may include a plurality of merged sub arrays. Each merged sub array may be arranged such that at least one side of the merged sub array is spaced apart from another merged sub array. For example, the plurality of merged sub arrays may extend in the first horizontal direction (e.g., the Y direction) and be arranged in parallel in the second horizontal direction (e.g., the X direction). As another example, the plurality of merged sub arrays may extend in the second horizontal direction (e.g., the X direction) and be arranged in parallel in the first horizontal direction (e.g., the Y direction). A structure in which the plurality of merged sub arrays are arranged is described below with reference to FIG. 10.

In one or more examples, although FIGS. 7A and 7B show that the merged sub array 200 includes four sub arrays merged therein, the present embodiment is not limited thereto. For example, the merged sub array 200 may include eight sub arrays merged therein. For example, the merged sub array 200 may include 4n (n is a natural number) sub arrays merged therein.

The merged sub array 200 may include a plurality of pads formed such that the peripheral circuit structure PCS is connected to the plurality of upper bit lines BL<1>, BL<2>, . . . , BL<2n−1>, and BL<2n>, the plurality of lower bit lines BL_B<1>, BL_B<2>, . . . , BL_B<2n−1>, and BL_B<2n>, the plurality of left word lines WL_L<1>, WL_L<2>, . . . , WL_L<2n−1>, and WL_L<2n>, and the plurality of right word lines WL_R<1>, WL_R<2>, . . . , WL_R<2n−1>, and WL_R<2n>.

For example, the merged sub array 200 may include first pads, second pads, and third pads. The first pads may connect the first BLSA 311 of the peripheral circuit structure PCS to the plurality of upper bit lines BL<1>, BL<2>, . . . , BL<2n−1>, and BL<2n>, the second pads may connect the second BLSA 312 of the peripheral circuit structure PCS to the plurality of lower bit lines BL_B<1>, BL_B<2>, . . . , BL_B<2n−1>, and BL_B<2n>, and the third pads may connect the first SWD 321 and the second SWD 322 of the peripheral circuit structure PCS to the plurality of left word lines WL_L<1>, WL_L<2>, . . . , WL_L<2n−1>, and WL_L<2n> and the plurality of right word lines WL_R<1>, WL_R<2>, . . . , WL_R<2n−1>, and WL_R<2n>. The embodiments of the present disclosure are not limited to any particular arrangement the pads. The pads may be arranged in a manner that optimizes bonding between CAS and PCS.

In one or more embodiments, the merged sub array 200 may include a first word line half group WLHG1, a second word line half group WLHG2, a first bit line half group BLHG1, and a second bit line half group BLHG2.

In one or more embodiments, the merged sub array 200 may include the plurality of (e.g., 2n), left word lines WL_L<1>, WL_L<2>, . . . , WL_L<2n−1>, and WL_L<2n>, the plurality of (e.g., 2n), right word lines WL_R<1>, WL_R<2>, . . . , WL_R<2n−1>, and WL_R<2n>, the plurality of, i.e., 2n, upper bit lines BL<1>, BL<2>, . . . , BL<2n−1>, and BL<2n>, and the plurality of (e.g., 2n), lower bit lines BL_B<1>, BL_B<2>, . . . , BL_B<2n−1>, and thus, the merged sub array 200 may include the first word line half group WLHG1 and the second word line half group WLHG2 each including n left word lines among the plurality of left word lines WL_L<1>, WL_L<2>, . . . , WL_L<2n−1>, and WL_L<2n> and n right word lines among the plurality of right word lines WL_R<1>, WL_R<2>, . . . , WL_R<2n−1>, and WL_R<2n> and include the first bit line half group BLHG1 and the second bit line half group BLHG2 each including n upper bit lines among the plurality of upper bit lines BL<1>, BL<2>, . . . , BL<2n−1>, and BL<2n> and n lower bit lines among the plurality of lower bit lines BL_B<1>, BL_B<2>, . . . , BL_B<2n−1>, and BL_B<2n>.

For example, the first word line half group WLHG1 may include n left word lines and n right word lines, and likewise, the second word line half group WLHG2 may also include the other n left word lines and the other n right word lines. The first bit line half group BLHG1 may include n upper bit lines and n lower bit lines, and likewise, the second bit line half group BLHG2 may also include the other n upper bit lines and the other n lower bit lines.

If it is assumed that n is 2, the merged sub array 200 may include four left word lines WL_L<1>, WL_L<2>, WL_L<3>, and WL_L<4>, four right word lines WL_R<1>, WL_R<2>, WL_R<3>, and WL_R<4>, four upper bit lines BL<1>, BL<2>, BL<3>, and BL<4>, and four lower bit lines BL_B<1>, BL_B<2>, BL_B<3>, and BL_B<4>.

For example, in the merged sub array 200, the first word line half group WLHG1 may include four odd word lines (e.g., WL_L<1>, WL_L<3>, WL_R<1>, and WL_R<3>), the second word line half group WLHG2 may include four even word lines (e.g., WL_L<2>, WL_L<4>, WL_R<2>, and WL_R<4>), the first bit line half group BLHG1 may include four upper bit lines (e.g., BL<1>, BL<2>, BL<3>, and BL<4>), and the second bit line half group BLHG2 may include four lower bit lines (e.g., BL_B<1>, BL_B<2>, BL_B<3>, and BL_B<4>).

As described above, a first word line half group and a second word line half group may divide a plurality of word lines into odd word lines and even word lines. A first bit line half group and a second bit line half group may divide a plurality of bit lines into upper bit lines and lower bit lines. However, the present embodiment is not limited thereto, and the first word line half group and the second word line half group may divide the plurality of word lines into left word lines and right word lines and the first bit line half group and the second bit line half group may divide the plurality of bit lines into odd bit lines and even bit lines. In one or more examples, the number of bit lines in each bit line group and the number of word lines in each word line group is not equal. For example, the number of bit lines in a first group of bit lines may be M, and the number of bit lines in a second group of bit lines may be N, where M is not equal to N. In another example, the number of word lines in a first group of word lines may be M, and the number of word lines in a second group of word lines may be N, where M is not equal to N.

For example, in the merged sub array 200, the first word line half group WLHG1 may include four left word lines (e.g., WL_L<1>, WL_L<2>, WL_L<3>, and WL_L<4>), the second word line half group WLHG2 may include four right word lines (e.g., WL_R<1>, WL_R<2>, WL_R<3>, and WL_R<4>), the first bit line half group BLHG1 may include four odd bit lines (e.g., BL<1>, BL<3>, BL_B<1>, and BL_B<3>), and the second bit line half group BLHG2 may include four even bit lines BL<2>, BL<4>, BL_B<2>, and BL_B<4>).

In one or more examples, the peripheral circuit structure PCS may include a peripheral circuit region in which a peripheral circuit is formed. A partial peripheral circuit may be formed in a partial region of the peripheral circuit region. The other partial peripheral circuit may be formed in the other partial region of the peripheral circuit region. The peripheral circuit may be configured to apply the word line driving voltage to a word line selected from among the plurality of left word lines WL_L<1>, WL_L<2>, . . . , WL_L<2n−1>, and WL_L<2n> and the plurality of right word lines WL_R<1>, WL_R<2>, . . . , WL_R<2n−1>, and WL_R<2n>. The peripheral circuit may be configured to sense data through at least one bit line selected from among the plurality of upper bit lines BL<1>, BL<2>, . . . , BL<2n−1>, and BL<2n> and the plurality of lower bit lines BL_B<1>, BL_B<2>, . . . , BL_B<2n−1>, and BL_B<2n>.

In one or more examples, the size of the spare space 350 of the merged bank 300 may be greater than the size of the spare space of one bank shown in FIG. 5. For example, when the four sub array regions 11, 12, 21, and 22 of FIG. 5 are merged to be the merged sub array 200 of FIGS. 7A and 7B and the four banks of FIG. 5 are merged to be the merged bank 300 of FIGS. 7A and 7B, the size of the spare space 350 of the merged bank 300 shown in FIGS. 7A and 7B may be four times greater than the size of the spare region SPARE of one bank of FIG. 5. For example, when 4n (n is a natural number) sub array regions of FIG. 5 are merged to be the merged sub array 200 of FIGS. 7A and 7B and 4n banks of FIG. 5 are merged to be the merged bank 300 of FIGS. 7A and 7B, the size of the spare space 350 of the merged bank 300 shown in FIGS. 7A and 7B may be 4n times greater than the size of the spare region SPARE of one bank of FIG. 5.

The spare space 350 of the peripheral circuit structure PCS may include a command decoder, an MRS/EMRS circuit, an address buffer, a data I/O circuit, a voltage generate circuit, a test circuit, or any other suitable circuit structure known to one of ordinary skill in the art.

The memory device 100B according to the embodiments of the present disclosure may include the merged sub array 200 in which a plurality of sub arrays included in the cell array structure CAS are merged, and word lines and bit lines included in the merged sub array 200 may be divided and arranged according to predetermined criteria to increase the size of the spare space 350 of the peripheral circuit structure PCS. If the size of the spare space 350 increases, the spare space 350 may include peripheral circuits, such as a command decoder, an MRS/EMRS circuit, an address buffer, a data I/O circuit, a voltage generate circuit, and a test circuit, and thus, the memory chip size may decrease.

In one or more examples, because the spare space 350 may include the peripheral circuit, a spare region may be efficiently used and the degree of memory integration may be improved.

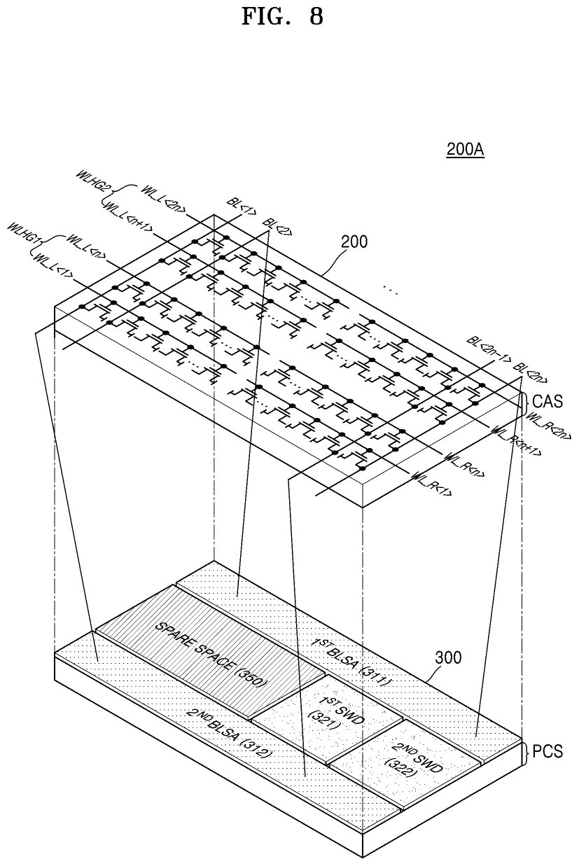

FIG. 8 is a perspective view illustrating a word line division structure and method of a memory device 200A according to one or more embodiments.

Referring to FIG. 8, the memory device 200A may include the cell array structure CAS and the peripheral circuit structure PCS. The cell array structure CAS may include the merged sub array 200. The merged sub array 200 may include the plurality of, i.e., 2n, left word lines WL_L<1>, WL_L<2>, . . . , WL_L<2n−1>, and WL_L<2n>, the plurality of, (e.g., 2n), right word lines WL_R<1>, WL_R<2>, . . . , WL_R<2n−1>, and WL_R<2n>, and a plurality of (e.g., 2n), bit lines BL<1>, BL<2>, BL<2n−1>, and BL<2n>. The peripheral circuit structure PCS may include the first BLSA 311, the second BLSA 312, the spare space 350, the first SWD 321, and the second SWD 322.

FIG. 8 differs from FIGS. 7A and 7B in that the plurality of left word lines WL_L<1>, WL_L<2>, . . . , WL_L<2n−1>, and WL_L<2n> and the plurality of right word lines WL_R<1>, WL_R<2>, . . . , WL_R<2n−1>, and WL_R<2n> are divided and the plurality of bit lines BL<1> to BL<n> are not divided.

In one or more embodiments, the odd right word lines among the plurality of right word lines WL_R<1>, WL_R<2>, . . . , WL_R<2n−1>, and WL_R<2n> may be connected to the first SWD 321 and the other right word lines (e.g., the even right word lines), may be connected to the second SWD 322. The odd left word lines among the plurality of left word lines WL_L<1>, WL_L<2>, . . . , WL_L<2n−1>, and WL_L<2n> may be connected to the first SWD 321 and the other left word lines (e.g., the even left word lines), may be connected to the second SWD 322. The odd bit lines among the plurality of bit lines BL<1> to BL<2n> may be connected to the first BLSA 311 and the other bit lines (e.g., the even bit lines), may be connected to the second BLSA 312.

In some embodiments, complementary bit lines of the odd bit lines BL<1>, BL<3>, . . . , BL<2n−3>, and BL<2n−1> may be a plurality of even bit lines of a merged sub array adjacent to the merged sub array 200 at a side of the first BLSA 311 and complementary bit lines of the even bit lines BL_B<2>, BL_B<4>, . . . , BL_B<2n−2>, and BL_B<2n> may be a plurality of odd bit lines of a merged sub array adjacent to the merged sub array 200 at a side of the second BLSA 312, but the some embodiments are not limited thereto.

The merged sub array 200 according to one or more embodiments may include the first word line half group WLHG1 and the second word line half group WLHG2 according to a word line division structure and method.

For example, the merged sub array 200 may include the first word line half group WLHG1 and the second word line half group WLHG2, respectively including odd word lines and even word lines, divided from the plurality of left word lines WL_L<1>, WL_L<2>, . . . , WL_L<2n−1>, and WL_L<2n> and the plurality of right word lines WL_R<1>, WL_R<2>, . . . , WL_R<2n−1>, and WL_R<2n>. The first word line half group WLHG1 may include n odd left word lines and n odd right word lines, and likewise, the second word line half group WLHG2 may also include the other n even left word lines and the other n even right word lines.

For example, if it is assumed that n is 4, the merged sub array 200 may include eight left word lines WL_L<1> to WL_L<8>, eight right word lines WL_R<1> to WL_R<8>, and four bit lines BL<1> to BL<4>.

The odd right word lines (e.g., WL_R<1>, WL_R<3>, WL_R<5>, and WL_R<7>) among the eight right word lines WL_R<1> to WL_R<8> may be connected to the first SWD 321, and the other right word lines such as the event right word lines (e.g., WL_R<2>, WL_R<4>, WL_R<6>, and WL_R<8>) may be connected to the second SWD 322. The odd left word lines (e.g., WL_L<1>, WL_L<3>, WL_L<5>, and WL_L<7>) among the eight left word lines WL_L<1> to WL_L<8> may be connected to the first SWD 321, and the other left word lines such as the event left word lines (e.g., WL_L<2>, WL_L<4>, WL_L<6>, and WL_L<8>) may be connected to the second SWD 322. The odd bit lines (e.g., BL<1> and BL<3>) among the four bit lines BL<1> to BL<4> may be connected to the first BLSA 311, and the other bit lines, i.e., the even bit lines (e.g., BL<2> and BL<4>) may be connected to the second BLSA 312.

However, the present embodiment is not limited thereto, and other embodiments may be possible.

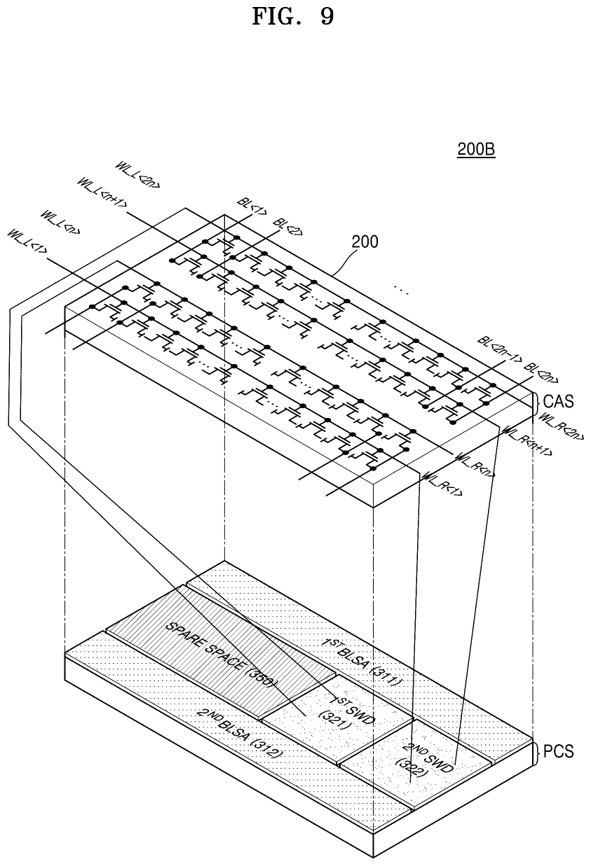

FIG. 9 is a perspective view illustrating a bit line division structure and method according to one or more embodiments.

Referring to FIG. 9, a memory device 200B may include the cell array structure CAS and the peripheral circuit structure PCS. The cell array structure CAS may include the merged sub array 200. The merged sub array 200 may include the plurality of (e.g., 2n) right word lines WL_R<1>, WL_R<n>, . . . , WL_R<n+1 >, and WL_R<2n>, the plurality of, (e.g., 2n) left word lines WL_L<1>, WL_L<n>, . . . , WL_L<n+1>, and WL_L<2n>, the plurality of (e.g., 2n), upper bit lines BL<1>, BL<2>, . . . , BL<2n−1>, and BL<2n>, and the plurality of (e.g., 2n), lower bit lines BL_B<1>, BL_B<2>, . . . , BL_B<2n−1>, and BL_B<2n>. The peripheral circuit structure PCS may include the first BLSA 311, the second BLSA 312, the spare space 350, the first SWD 321, and the second SWD 322.

FIG. 9 differs from FIGS. 7A and 7B in that the n word lines WL<1>, WL<2>, . . . , WL<n−1>, and WL<n> are not divided and the plurality of upper bit lines BL<1>, BL<2>, . . . , BL<2n−1>, and BL<2n> and the plurality of lower bit lines BL_B<1>, BL_B<2>, . . . , BL_B<2n−1>, and BL_B<2n> are divided.

In one or more embodiments, the odd word lines among the n word lines WL<1>, WL<2>, . . . , WL<n−1>, and WL<n> may be connected to the first SWD 321 and the other word lines, such as the even word lines, may be connected to the second SWD 322. The plurality of upper bit lines BL<1>, BL<2>, . . . , BL<2n−1>, and BL<2n> may be connected to the first BLSA 311 and the plurality of lower bit lines BL_B<1>, BL_B<2>, . . . , BL_B<2n−1>, and BL_B<2n> may be connected to the second BLSA 312.

The merged sub array 200 according to one or more embodiments may include the first bit line half group BLHG1 and the second bit line half group BLHG2 according to a bit line division structure and method.

For example, the first bit line half group BLHG1 may include the plurality of upper bit lines BL<1>, BL<2>, . . . , BL<2n−1>, and BL<2n> and the second bit line half group BLHG2 may include the plurality of lower bit lines BL_B<1>, BL_B<2>, . . . , BL_B<2n−1>, and BL_B<2n>.

When n is 4, the merged sub array 200 may include four word lines WL<1> to WL<4>, eight upper bit lines BL<1> to BL<8>, and eight lower bit lines BL_B<1> to BL_B<8>.

The first bit line half group BLHG1 of the merged sub array 200 may include the eight upper bit lines BL<1> to BL<8> and the second bit line half group BLHG2 may include the eight lower bit lines BL_B<1> to BL_B<8>. The first bit line half group BLHG1 may be connected to the first BLSA 311 and the second bit line half group BLHG2 may be connected to the second BLSA 312. The odd word lines among the n word lines WL<1>, WL<2>, . . . , WL<n−1>, and WL<n> may be connected to the first SWD 321 and the other word lines, such as, the even word lines, may be connected to the second SWD 322.

FIG. 10 is a perspective view illustrating a word line and bit line division structure and method according to one or more embodiments.

Referring to FIG. 10, a memory device 500A may include first and second merged sub arrays 501 and 502 and two merged banks. The cell array structure CAS may include the first and second merged sub arrays 501 and 502. The merged sub array 200 shown in FIGS. 7A and 7B may be applied to the first and second merged sub arrays 501 and 502 of FIG. 10. The description made with reference to FIGS. 7A and 7B is omitted herein.

Each of the first and second merged sub arrays 501 and 502 may include the plurality of, i.e., 2n, left word lines WL_L<1>, WL_L<2>, . . . , WL_L<2n−1>, and WL_L<2n>, the plurality of, i.e., 2n, right word lines WL_R<1>, WL_R<2>, . . . , WL_R<2n−1>, and WL_R<2n>, the plurality of upper bit lines BL<1>, BL<2>, . . . , BL<2n−1>, and BL<2n>, and the plurality of lower bit lines BL_B<1>, BL_B<2>, . . . , BL_B<2n−1>, and BL_B<2n>.

Each of the first and second merged sub arrays 501 and 502 may include the first word line half group WLHG1 and the second word line half group WLHG2 divided from the plurality of left word lines WL_L<1>, WL_L<2>, . . . , WL_L<2n−1>, and WL_L<2n> and the plurality of right word lines WL_R<1>, WL_R<2>, . . . , WL_R<2n−1>, and WL_R<2n> according to predetermined criteria. In one or more examples, each of the first and second merged sub arrays 501 and 502 may include the first bit line half group BLHG1 and the second bit line half group BLHG2 divided from the plurality of upper bit lines BL<1>, BL<2>, . . . , BL<2n−1>, and BL<2n> and the plurality of lower bit lines BL_B<1>, BL_B<2>, . . . , BL_B<2n−1>, and BL_B<2n> according to predetermined criteria.

As an example of predetermined criteria, in each of the first and second merged sub arrays 501 and 502, the plurality of left word lines WL_L<1>, WL_L<2>, . . . , WL_L<2n−1>, and WL_L<2n> may be divided into two groups of n left word lines, the plurality of right word lines WL_R<1>, WL_R<2>, . . . , WL_R<2n−1>, and WL_R<2n> may be divided into two groups of n right word lines, the plurality of upper bit lines BL<1>, BL<2>, . . . , BL<2n−1>, and BL<2n> may be divided into two groups of n upper bit lines, and the plurality of lower bit lines BL_B<1>, BL_B<2>, . . . , BL_B<2n−1>, and BL_B<2n> may be divided into two groups of n lower bit lines.

As an example of predetermined criteria, in each of the first and second merged sub arrays 501 and 502, the plurality of left word lines WL_L<1>, WL_L<2>, . . . , WL_L<2n−1>, and WL_L<2n> and the plurality of right word lines WL_R<1>, WL_R<2>, . . . , WL_R<2n−1>, and WL_R<2n> may be divided into odd word lines and even word lines, and the plurality of upper bit lines BL<1>, BL<2>, . . . , BL<2n−1>, and BL<2n> and the plurality of lower bit lines BL_B<1>, BL_B<2>, . . . , BL_B<2n−1>, and BL_B<2n> may be divided into odd bit lines and even bit lines.

The cell array structure CAS according to the embodiments of the present disclosure may include the first and second merged sub arrays 501 and 502, wherein word lines and bit lines included in each of the first and second merged sub arrays 501 and 502 may be divided and arranged according to predetermined criteria. By dividing and arranging word lines and bit lines, the size of a spare region of a peripheral circuit structure may increase, and because peripheral circuits may be included in the spare region, the memory chip size may decrease and the degree of memory integration may be improved.

Referring to FIG. 10, the first merged sub array 501 and the second merged sub array 502 may be included. The first merged sub array 501 may include a plurality of word lines and a plurality of bit lines in the cell array structure CAS and include the first BLSA 311, the second BLSA 312, the first SWD 321, the second SWD 322, and the spare space 350 in the peripheral circuit structure PCS. The second merged sub array 502 may also include a plurality of word lines and a plurality of bit lines in the cell array structure CAS and include the first BLSA 311, the second BLSA 312, the first SWD 321, the second SWD 322, and the spare space 350 in the peripheral circuit structure PCS.

The plurality of word lines and the plurality of bit lines included in the cell array structure CAS of each of the first and second merged sub arrays 501 and 502 may be connected to the first and second SWDs 321 and 322 and the first and second BLSAs 311 and 312 of the peripheral circuit structure PCS, respectively, as shown in FGS. 7A and 7B.

FIG. 10 differs from FGS. 7A and 7B in that two merged sub arrays as shown in FIG. 7A or 7B are symmetrically formed. The first and second merged sub arrays 501 and 502 shown in FIG. 10 may be formed such that a spare space of the first merged sub array 501 faces a spare space of the second merged sub array 502. Therefore, the size of a spare space of a merged bank (including the two merged banks) shown in FIG. 10 may be eight times greater than the size of the spare space 350 of the merged bank 300 of FIG. 7A or 7B.

The word lines and the bit lines included in each of the first and second merged sub arrays 501 and 502 may be divided and arranged according to predetermined criteria. By dividing and arranging word lines and bit lines, the size of a spare region of a peripheral circuit structure may increase, and because peripheral circuits may be included in the spare region, the memory chip size may decrease and the degree of memory integration may be improved.

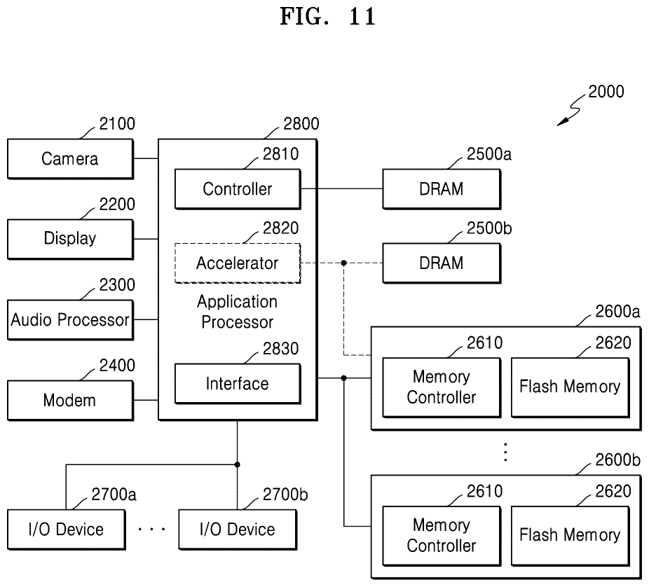

FIG. 11 is a block diagram illustrating an electronic device 2000 including a memory device according to one or more embodiments.

Referring to FIG. 11, the electronic device 2000 may include a camera 2100, a display 2200, an audio processor 2300, a modem 2400, DRAMs 2500a and 2500b, flash memories 2600a and 2600b, I/O devices 2700a and 2700b, and an application processor (AP) 2800. The electronic device 2000 may be implemented by a laptop computer, a mobile terminal, a smartphone, a tablet personal computer (PC), a wearable device, a healthcare device, or an Internet of Things (IoT) device. Alternatively, the electronic device 2000 may be implemented by a server or a PC.

The camera 2100 may capture a still image or a moving picture according to control by a user and store the captured image/video data therein or transmit the captured image/video data to the display 2200. The audio processor 2300 may process audio data included in content in the flash memories 2600a and 2600b or from a network. The modem 2400 may modulate and transmit a signal for wired/wireless data transmission and reception and demodulate a signal into an original signal at a reception side. The I/O devices 2700a and 2700b may include devices, such as a universal serial bus (USB), a storage, a digital camera, a secure digital (SD) card, a digital versatile disc (DVD), a network adapter, and a touch screen, configured to provide a digital input and/or output function.

The AP 2800 may control a general operation of the electronic device 2000. The AP 2800 may include a controller 2810, an accelerator 2820, and an interface 2830. The AP 2800 may control the display 2200 to display, on the display 2200, a portion of content stored in the flash memories 2600a and 2600b. If a user input is received through the I/O devices 2700a and 2700b, the AP 2800 may perform a control operation corresponding to the user input. The AP 2800 may include the accelerator 2820 that is an exclusive circuit for artificial intelligence (AI) data computation, or the accelerator 2820 may be provided separately from the AP 2800. The DRAM 2500b may be additionally mounted in the accelerator 2820. An accelerator is a function block configured to professionally perform a particular function of the AP 2800 and may include a graphics processing unit (GPU) that is a function block configured to professionally perform graphics data processing, a neural processing unit (NPU) that is a block configured to professionally perform AI computation and inference, and a data processing unit (DPU) that is a block configured to professionally perform data transmission.

The electronic device 2000 may include a plurality of DRAMs. The AP 2800 may control the DRAMs 2500a and 2500b through a command and a mode register set (MRS) according to a Joint Electron Device Engineering Council (JEDEC) standard or communicate with the DRAMs 2500a and 2500b by setting a DRAM interface protocol to use company-specific functions, such as low voltage/high speed/reliability and the like, and a cyclic redundancy check (CRC)/error correction code (ECC) function. For example, the AP 2800 may communicate with the DRAM 2500a by using an interface, which meets a JEDEC standard, such as low power double data rate 4 (LPDDR4) or LPDDR5, and the accelerator 2820 may communicate with the DRAM 2500b by setting a new DRAM interface protocol to control the DRAM 2500b having a higher bandwidth than the DRAM 2500a, the DRAM 2500b being for an accelerator.

Although FIG. 11 shows only the DRAMs 2500a and 2500b, the present embodiment is not limited thereto, and only if the bandwidth, the reaction speed, and the voltage conditions of the AP 2800 or the accelerator 2820 are satisfied, any memory, such as parameter random access memory (PRAM), static random access memory (SRAM), magnetic random access memory (MRAM), resistive random access memory (RRAM), ferroelectric random access memory (FRAM), or hybrid RAM, may be used. The DRAMs 2500a and 2500b have a relatively less latency and bandwidth than the I/O devices 2700a and 2700b or the flash memories 2600a and 2600b. The DRAMs 2500a and 2500b may be initialized at a power-on time point of the electronic device 2000 and used as a temporary storage of an operating system and application data by loading the operating system and the application data thereon or used as an execution space of various kinds of software codes.

In the DRAMs 2500a and 2500b, the four fundamental arithmetic operations of addition/subtraction/multiplication/division, a vector operation, an address calculation, or a fast Fourier transform (FFT) operation may be performed. In one or more examples, in the DRAMs 2500a and 2500b, a functional function for execution used for inference may be performed. Herein, inference may be performed by a deep learning algorithm using an artificial neural network. The deep learning algorithm may include a training operation of training a model through various pieces of data and an inference operation of recognizing data by using the trained model. In one or more embodiments, an image captured by a user through the camera 2100 may be signal-processed and stored in the DRAM 2500b, and the accelerator 2820 may perform an AI data computation for recognizing data by using data stored in the DRAM 2500b and a function used for inference.

The electronic device 2000 may include a plurality of storages or the flash memories 2600a and 2600b having a greater capacity than the DRAMs 2500a and 2500b. The accelerator 2820 may perform the training operation and an AI data computation by using the flash memories 2600a and 2600b. In one or more embodiments, each of the flash memories 2600a and 2600b may include a memory controller 2610 and a flash memory device 2620 and relatively efficiently perform, by using a computation device included in the memory controller 2610, the training operation and an inference AI data computation to be performed by the AP 2800 and/or the accelerator 2820. The flash memories 2600a and 2600b may store pictures taken through the camera 2100 or store data received through a data network. For example, augmented reality/virtual reality, high definition (HD), or ultra-high definition (UHD) content may be stored in the flash memories 2600a and 2600b.

In the electronic device 2000, the DRAMs 2500a and 2500b may include memory devices described with reference to FIGS. 1 to 10. A memory device may include a peripheral circuit structure formed on a semiconductor substrate and a cell array structure on the peripheral circuit structure so as to overlap the peripheral circuit structure in the vertical direction. The cell array structure may include a plurality of memory blocks in a memory cell region in which a plurality of vertical channel transistor structures and a plurality of capacitor structures respectively connected to the plurality of vertical channel transistor structures are formed. The cell array structure may include a merged sub array. The merged sub array may include a first word line half group and a second word line half group obtained by dividing a plurality of left word lines and a plurality of right word lines according to predetermined criteria. In one or more examples, the merged sub array may include a first bit line half group and a second bit line half group obtained by dividing a plurality of upper bit lines and a plurality of lower bit lines according to predetermined criteria. The peripheral circuit structure may include a peripheral circuit region in which a merged bank and a peripheral circuit are formed. The merged bank may include a first BLSA, a second BLSA, an SWD, and a spare space. As the spare space of the merged bank increases, peripheral circuits may be included in the increased spare space, and thus, the memory chip size may decrease.

A memory device according to the embodiments of the present disclosure may include a merged sub array in which a plurality of sub arrays included in a cell array structure are merged, wherein word lines and bit lines included in the merged sub array may be divided and arranged according to predetermined criteria to increase the size of a spare region of a peripheral circuit structure. If the size of a spare space increases, the spare space may include peripheral circuits, such as a command decoder, an MRS/EMRS circuit, an address buffer, a data I/O circuit, a voltage generate circuit, and a test circuit, and thus, the memory chip size may decrease. In one or more examples, because the spare space may include the peripheral circuit, the spare space may be efficiently used and the degree of memory integration may be improved.

While the embodiments of the present disclosure have been particularly shown and described with reference to embodiments thereof, it will be understood that various changes in form and details may be made therein without departing from the spirit and scope of the following claims.

What is claimed is:

1. A memory device comprising:
a peripheral circuit structure; and
a cell array structure disposed on the peripheral circuit structure,
wherein the cell array structure overlaps the peripheral circuit structure in a first direction, wherein the cell array structure comprises a merged sub array in which at least four sub array regions are merged,
wherein the merged sub array comprises a memory cell region comprising:
a plurality of first bit lines and a plurality of second bit lines arranged in a second direction perpendicular to the first direction; and
a plurality of first word lines and a plurality of second word lines arranged in a third direction that is perpendicular to the second direction,
wherein the peripheral circuit structure comprises a merged bank in which at least four banks are merged, and
wherein the merged bank comprises:
a first bit line sense amplifier (BLSA) configured to sense a voltage difference of the plurality of first bit lines,
a second BLSA configured to sense a voltage difference of the plurality of second bit lines,
a first sub word line driver (SWD) configured to drive even numbered word lines among the plurality of first word lines and even numbered word lines among the plurality of second word lines, and
a second SWD configured to drive odd numbered word lines among the plurality of first word lines and odd numbered word lines among the plurality of second word lines, and
wherein a spare space is defined between a first area corresponding to the plurality of first bit lines and a second area corresponding to the plurality of second bit lines.

2. The memory device of claim 1, wherein the memory cell region further comprises a plurality of memory cells, and each of the plurality of memory cells has a vertical channel transistor (VCT) structure.

3. The memory device of claim 2, wherein each of the plurality of memory cells comprises:
a cell transistor connected to a word line from the plurality of first word lines or the plurality of second word lines, a bit line from the plurality of first or second bit lines, and a back gate line; and
a cell capacitor connected between a first electrode of the cell transistor and ground.

4. The memory device of claim 1, wherein the merged sub array comprises:
a first word line half group and a second word line half group each comprising n first word lines among the plurality of first word lines and n second word lines among the plurality of second word lines; and
a first bit line half group and a second bit line half group each comprising n first bit lines among the plurality of first bit lines and n second bit lines among the plurality of second bit lines.

5. The memory device of claim 4, wherein the first word line half group comprises first and second word lines from the plurality of first word lines, first and second word lines from the plurality second word lines, and
wherein the second word line half group comprises third and fourth word lines from the plurality of first word lines, and third and fourth second word lines from the plurality of second word lines.

6. The memory device of claim 4, wherein the first bit line half group comprises first and second bit lines from the plurality of first bit lines and first and second bit lines from the plurality of second bit lines, and
wherein the second bit line half group comprises third and fourth bit lines from the plurality of first bit lines and third and fourth bit lines from the plurality of second bit lines.

7. The memory device of claim 1, wherein the merged sub array comprises:
a first word line half group comprising odd numbered word lines among the plurality of first word lines and the plurality of second word lines;
a second word line half group comprising even numbered word lines among the plurality of first word lines and the plurality of second word lines;
a first bit line half group comprising odd numbered bit lines among the plurality of first bit lines and the plurality of second bit lines; and
a second bit line half group comprising even numbered bit lines among the plurality of first bit lines and the plurality of second bit lines.

8. The memory device of claim 7, wherein the first word line half group comprises first and third word lines from the plurality of first word lines and first and third word lines from the plurality of second word lines, and
wherein the second word line half group comprises second and fourth word lines from the plurality of first word lines and second and fourth word lines from the plurality of second word lines.

9. The memory device of claim 7, wherein the first bit line half group comprises first and third bit lines from the plurality of first bit lines and first and third bit lines from the plurality of second bit lines, and
wherein the second bit line half group comprises second and fourth bit lines from the plurality of first bit lines and second and fourth bit lines from the plurality of second bit lines.

10. The memory device of claim 1, wherein the spare space of the merged bank is greater than a spare space of one bank.

11. The memory device of claim 10, wherein a peripheral circuit is formed in the spare space of the merged bank.

12. A memory device comprising:
a peripheral circuit structure; and
a cell array structure on the peripheral circuit structure
wherein the cell array structure overlaps the peripheral circuit structure in a first direction,
wherein the cell array structure comprises a merged sub array in which at least 4n sub array regions are merged,
wherein n is a natural greater than zero,
wherein the merged sub array comprises:
a first bit line half group and a second bit line half group obtained by dividing a plurality of first bit lines and a plurality of second bit lines arranged in a second direction perpendicular to the first direction, and
a first word line half group and a second word line half group obtained by dividing a plurality of first word lines and a plurality of second word lines arranged in a third direction that is perpendicular to the second direction, and
wherein the peripheral circuit structure comprises a merged bank in which at least 4n banks are merged.

13. The memory device of claim 12, wherein each of the first bit line half group and the second bit line half group is formed by n bit lines among the plurality of first bit lines and n bit lines among the plurality of second bit lines, and each of the first word line half group and the second word line half group is formed by n word lines among the plurality of first word lines and n word lines among the plurality of second word lines.

14. The memory device of claim 13, wherein, n is 4, the first bit line half group comprises first to fourth bit lines from the plurality of first bit lines and first to fourth bit lines from the plurality of second bit lines, the second bit line half group comprises fifth to eighth bit lines from the plurality of first bit lines and fifth to eighth bit lines from the plurality of second, the first word line half group comprises first to fourth word lines from the plurality of first word lines and first to fourth word lines from the plurality of second word lines, and the second word line half group comprises fifth to eighth word lines from the plurality of first word lines and fifth to eighth word lines from the plurality of second word lines.

15. The memory device of claim 12, wherein the first bit line half group and the second bit line half group are formed by dividing the plurality of first bit lines and the plurality of second bit lines into odd and even numbered bit lines, respectively, and wherein the first word line half group and the second word line half group are formed by dividing the plurality of first word lines and the plurality of second word lines into odd and even numbered word lines, respectively.

16. The memory device of claim 15, wherein the first bit line half group comprises odd numbered bit lines from the plurality of first bit lines and odd numbered bit lines from the plurality of second bit lines, the second bit line half group comprises even numbered bit lines from the plurality of first bit lines and even numbered bit lines from the plurality of second bit lines, the first word line half group comprises odd numbered word lines from the plurality of first word lines and odd numbered word lines from the plurality of second word lines, and the second word line half group comprises even numbered word lines from the plurality of first word lines and even numbered word lines from the plurality of second word lines.

17. The memory device of claim 12, wherein a spare space of the merged bank is 4n times greater than a spare space of each bank, wherein n is a natural number greater than zero.

18. A memory device comprising:
a peripheral circuit structure; and
a cell array structure on the peripheral circuit structure,
wherein the cell array structure overlaps the peripheral circuit structure in a first direction,
wherein the cell array structure comprises a merged sub array in which at least 4n sub array regions are merged,
wherein n is a natural number greater than zero,
wherein the merged sub array comprises a memory cell region comprises:
a plurality of first bit lines and a plurality of second bit lines arranged in a second direction perpendicular to the first direction; and
a plurality of first word lines and a plurality of second word lines arranged in a third direction perpendicular to the second direction,
wherein the memory cell region comprises a first bit line half group and a second bit line half group obtained by dividing the plurality of first bit lines and the plurality of second bit lines according to first predetermined criteria and a first word line half group and a second word line half group obtained by dividing the plurality of first word lines and the plurality of second word lines according to second predetermined criteria,
wherein the peripheral circuit structure comprises a merged bank in which at least 4n banks are merged, and
wherein the merged bank comprises:
a first bit line sense amplifier (BLSA) configured to sense a voltage difference of the plurality of first bit lines,
a second BLSA configured to sense a voltage difference of the plurality of second bit lines,
a first sub word line driver (SWD) configured to drive even numbered word lines among the plurality of first word lines and even numbered word lines among the plurality of second word lines,
a second SWD configured to drive odd numbered word lines among the plurality of first word lines and odd numbered word lines among the plurality of second word lines, and
wherein a spare space is defined between a first area corresponding to the plurality of first bit lines and a second area corresponding to the plurality of second bit lines.

19. The memory device of claim 18, wherein the plurality of first bit lines, the plurality of second bit lines, the plurality of first word lines, and the plurality of second word lines are each divided by a 2n unit basis,
wherein the first bit line half group comprises 2n bit lines among the plurality of first bit lines and 2n bit lines among the plurality of second bit lines, the second bit line half group comprises the remaining 2n bit lines among the plurality of first bit lines and the remaining 2n bit lines among the plurality of second bit lines, and
wherein the first word line half group comprises 2n word lines among the plurality of first word lines and 2n word lines among the plurality of second word lines, and the second word line half group comprises the remaining 2n word lines among the plurality of first word lines and the remaining 2n word lines among the plurality of second word lines.

20. The memory device of claim 18, wherein the plurality of first bit lines, the plurality of second bit lines, the plurality of first word lines, and the plurality of second word lines are each divided into odd numbered and even numbered lines,
wherein the first bit line half group comprises odd numbered bit lines from the plurality of first bit lines and odd numbered bit lines from the plurality of second bit lines,
wherein the second bit line half group comprises even numbered bit lines from the plurality of first bit lines and even numbered bit lines from the plurality of second bit lines,
wherein the first word line half group comprises odd numbered word lines from the plurality of first word lines and odd numbered word lines from the plurality of second word lines, and
wherein the second word line half group comprises even numbered word lines from the plurality of first word lines and even numbered word lines from the plurality of second word lines.
